(19) United States
(12) Patent Application Publication
(10) Pub. No.: US 2026/0059698 A1
(43) Pub. Date: Feb. 26, 2026

(54) INTEGRATED PUMP WATER-COOLING GRID FOR COMPUTER

(71) Applicant: DONGGUAN GASSENDI TECHNOLOGY CO., LTD., Dongguan (CN)

(72) Inventors: Hongming ZHU, Yueqing (CN); Zhicheng LIN, Guangzhou (CN)

(73) Assignee: DONGGUAN GASSENDI TECHNOLOGY CO., LTD., Dongguan (CN)

(21) Appl. No.: 18/884,415

(22) Filed: Sep. 13, 2024

(30) Foreign Application Priority Data
Aug. 21, 2024 (CN) 202422037246.8

(51) Int. Cl. H05K 7/20; G06F 1/20

(52) U.S. Cl. CPC H05K 7/20272; G06F 1/206; H05K 7/20281; H05K 7/20263

(57) ABSTRACT

An integrated pump water-cooling grid for a computer includes a water tank, an impeller and a driving device. The water tank includes a first water tank and a second water tank, a plurality of pipe bodies are disposed between the first water tank and the second water tank, and radiating fins are disposed between the adjacent pipe bodies; the first water tank is provided with at least two spaced-apart liquid chambers, and the two liquid chambers are respectively connected to a water outlet and a water inlet; the impeller is pivotally installed in the liquid chamber; a partition is provided on the first water tank at a position far away from the pipe bodies, and a radially extending disc is provided on a side wall of the impeller close to the partition, and when the impeller rotates, it can drive the liquid to flow.

### CROSS-REFERENCE TO RELATED APPLICATIONS

This application claims priority to Chinese Patent Application No. 202422037246.8, filed on Aug. 21, 2024, the content of which is incorporated herein by reference in its entirety.

### TECHNICAL FIELD

The present disclosure relates to the technical field of water-cooling grids, in particular to an integrated pump water-cooling grid for a computer.

### BACKGROUND

The existing computer heat exchanger, also known as a water-cooling grid, employs a combination of pipe bodies and radiating fins (or fans) to achieve heat exchange between the heated liquid and the outside through the radiating fins.

A water tank, pipe bodies and a water pump are integrally designed in the prior art. However, due to the large volume of the water pump, the volume of the water tank will be reduced accordingly. In order to increase the volume of the water tank (that is, to store more liquid), the overall structure of the water tank will be also relatively complicated accordingly. Taking Chinese Patent Publication CN215867735U as an example, in order to realize the relative work of a stator and a rotor, a concave-convex structure is designed, and an impeller is further enabled to be located in a water chamber, which avoids the contact between electronic components and the water chamber. However, the mold production cost is relatively high, and the thickness is larger, which makes the overall volume relatively large.

### SUMMARY

The main purpose of the present disclosure is to provide an integrated pump water-cooling grid for a computer, aiming to improve the structure of the water-cooling grid, make the structure of a water pump smaller, and enable the water pump to have a smaller thickness, while ensuring the predetermined volume of the water tank, with a simple structure, thus effectively reducing production costs.

In order to achieve the above purpose, the present disclosure provides an integrated pump water-cooling grid for a computer, including:
a water tank, including a first water tank and a second water tank, a plurality of pipe bodies being disposed between the first water tank and the second water tank, and radiating fins being disposed between the adjacent pipe bodies; the first water tank being provided with at least two spaced-apart liquid chambers, and the two liquid chambers being respectively connected to a water outlet and a water inlet;
an impeller, pivotally installed in the liquid chamber, a first partition being provided on the first water tank at a position far away from the pipe bodies, a disc being provided on a side wall of the impeller close to the first partition, and the disc extending along the radial direction of the impeller; and
a driving device, including a stator and a rotor, where the stator is disposed on an outer wall of the first partition, the rotor cooperates with the stator, the rotor and the stator are disposed along a radial direction, the rotor is located on one side of an inner wall of the stator, the magnetic fields of the stator and the rotor are tangent along an axial direction.

The rotor is disposed on the disc, or the rotor drives the disc to rotate by means of an intermediate piece, and when the impeller rotates, it can drive the liquid to flow.

In practical work, there may be one set of driving device or two sets of driving devices, that is, the one set of driving device is installed inside any one of the liquid chambers, or the two sets of driving devices are respectively installed inside the two liquid chambers.

When the impeller rotates, the liquid passes through the water inlet, the first liquid chamber, the pipe bodies, the second water tank, the second liquid chamber (one driving device may be disposed at the position of the second liquid chamber, of course, both of the two driving devices may be available, and when both of them are disposed, the direction of the water outlet and the water inlet can be not considered), and the water outlet in turn, thereby achieving heat exchange of the heated liquid and transporting the cooled liquid to the heating elements through the water outlet; therefore, cooling is realized.

The embodiments of this application have the following technical effects.

Firstly, the liquid chambers and an outer wall of the first water tank are independent of each other, so that the liquid will not affect circuit components, and the service life and safety of the driving device are guaranteed.

Secondly, the stator and the rotor are disposed radially to achieve axial tangency, so that the overall thickness of the driving device is reduced; furthermore, the first water tank and the water pump are integrally designed, making the structure simpler and the volume smaller, which effectively improves the aesthetics of a water cooling structure for the computer.

Thirdly, the structure is simpler, and there is no need for a concave-convex structure between the water chamber and a pump chamber to achieve the tangency between the stator and the rotor; a radial structure is simply adopted, so that the mold production cost is lower and the market competitiveness is effectively improved.

Lastly, under the same output torque, speed and power, compared with a radial flux motor, the axial flux motor (i.e., the driving device mentioned in the present application) has the advantages that: the axial size is shortened by 50% or more, which is more suitable for occasions with high space requirements; and the weight is reduced by about 50%, so that the maneuverability of equipment can be greatly improved, and lightweight is achieved.

The direction of a pump seat may be set vertically or radially, and the corresponding direction can also be changed accordingly.

### BRIEF DESCRIPTION OF THE DRAWINGS

FIG. 1 is a sectional view of the present disclosure.

FIG. 2 shows an exploded view I of the present disclosure.

FIG. 3 shows an exploded view II of the present disclosure.

FIG. 4 is a schematic diagram of the first embodiment.

FIG. 5 is a schematic diagram of the second embodiment.

FIG. 6 is a schematic diagram of the present disclosure.

FIG. 7 is a partially enlarged schematic diagram.

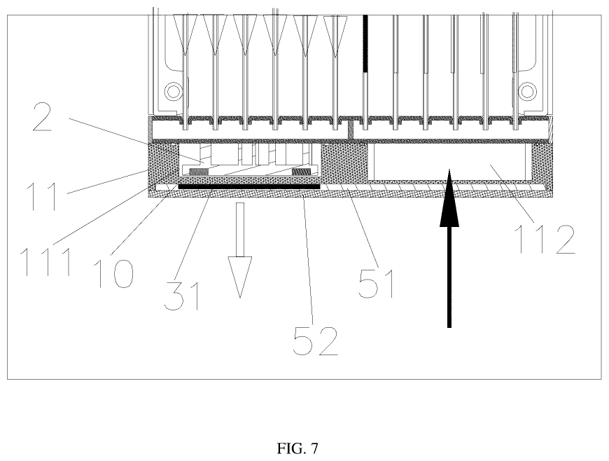

FIG. 8 is a schematic diagram showing the cooperation between a stator and a rotor.

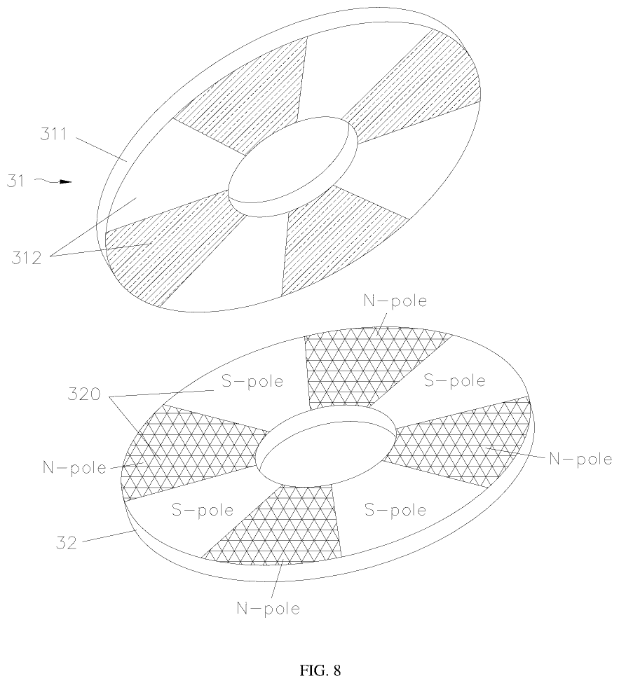

FIG. 9 is a schematic diagram showing the connection of a control device, a driving device and a sensor.

### DETAILED DESCRIPTION OF THE EMBODIMENTS

The technical solutions in embodiments of the present disclosure will be described clearly and completely hereinafter with reference to the accompanying drawings. Apparently, the described embodiments are only a part rather than all of the embodiments of the present disclosure. Based on the embodiments of the present disclosure, all other embodiments obtained by those of ordinary skill in the art without making creative efforts shall fall within the protection scope of the present disclosure.

It should be noted that if there are directional indications (such as upper, lower, left, right, front, back, top, bottom, inner, outer, vertical, horizontal, longitudinal, counterclockwise, clockwise, circumferential, radial, axial.) involved in the embodiments of the present disclosure, the directional indications are only used to explain a relative position relationship and motion situation between components in a specific posture (as shown in the figure). If the specific posture changes, the directional indication also changes accordingly.

In addition, if there are descriptions related to “first”, “second”, and the like in the embodiments of the present disclosure, the descriptions of “first”, “second”, and the like are only used for descriptive purposes, and cannot be understood as indicating or implying their relative importance or implying the number of indicated technical features. Therefore, the features defined with “first” and “second” may explicitly or implicitly include at least one of these features. Moreover, the technical solutions of various embodiments can be combined with each other, which must be based on what those of ordinary skill in the art can achieve. When the combination of the technical solutions is contradictory or impossible to achieve, it should be considered that the combination of such technical solutions does not exist and is not within the scope of protection of the present disclosure.

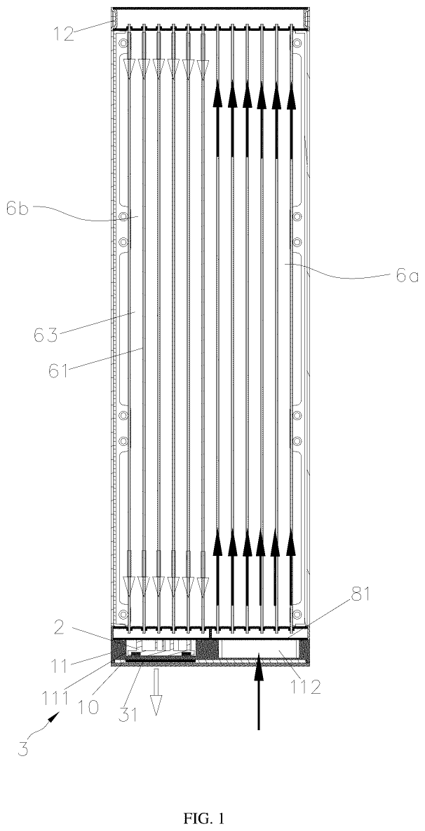

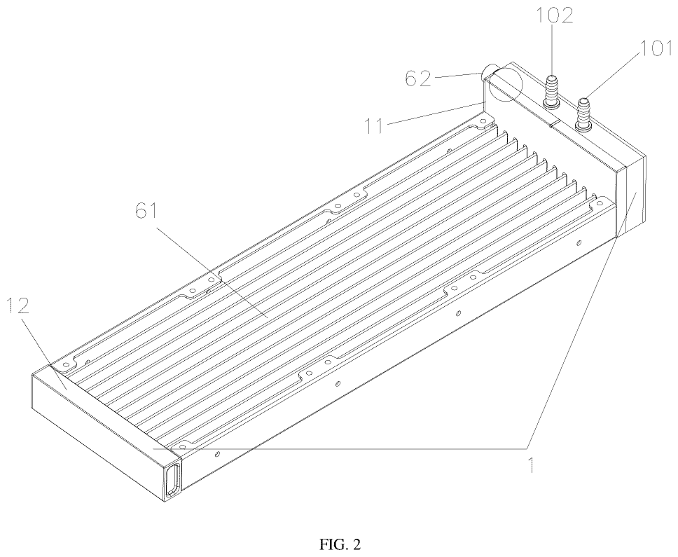

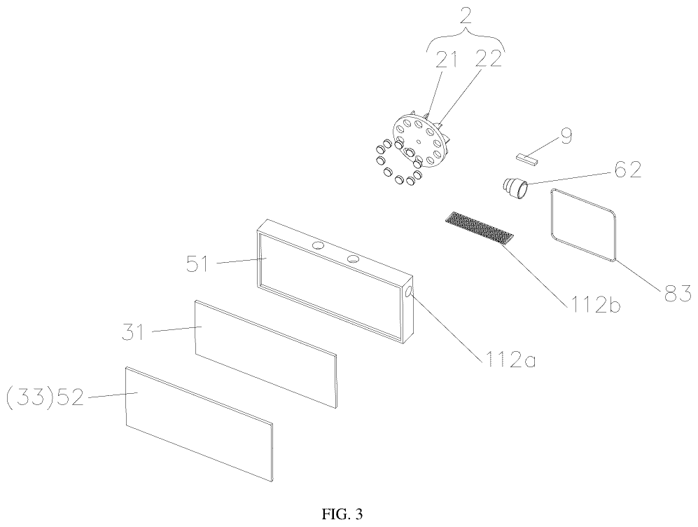

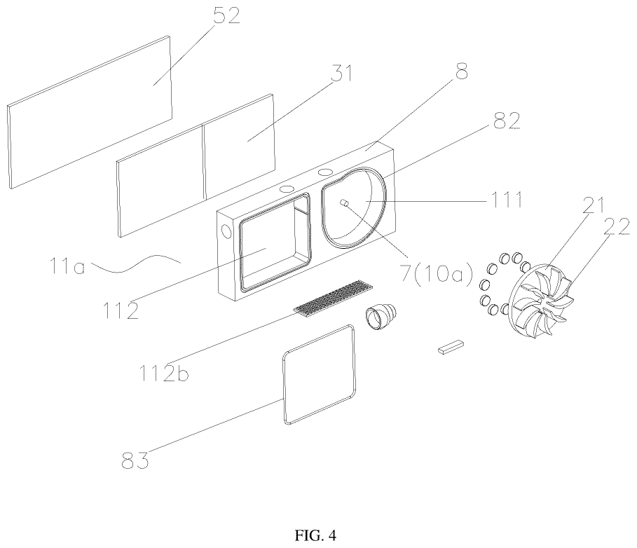

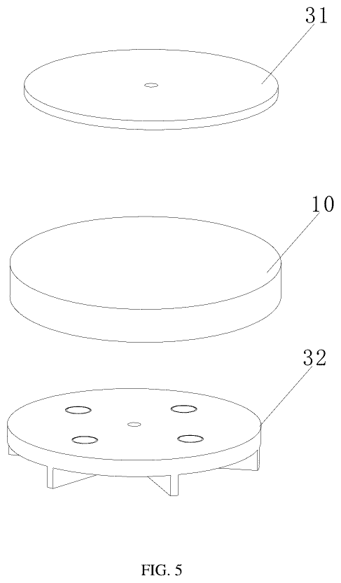

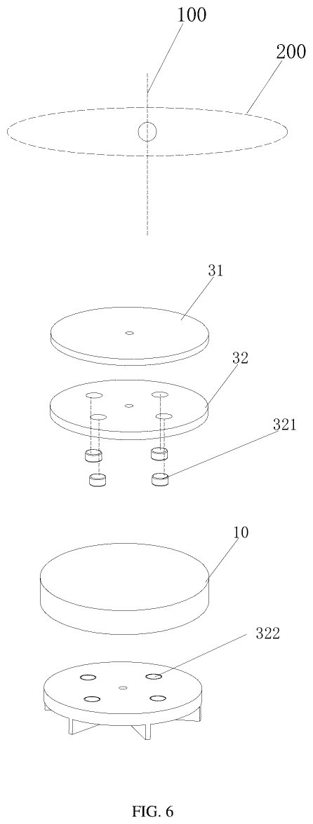

As shown in FIG. 1 to FIG. 6, an integrated pump water-cooling grid for a computer includes:
a water tank, including a first water tank 11 and a second water tank 12, a plurality of pipe bodies 61 being disposed between the first water tank 11 and the second water tank 12, and radiating fins 63 being disposed between the adjacent pipe bodies 61; the first water tank 11 being provided with at least two spaced-apart liquid chambers 11a, and the two liquid chambers 11a being respectively connected to a water outlet 101 and a water inlet 102;
an impeller 2, pivotally installed in the liquid chamber 11a, a first partition 10 being provided on the first water tank 11 at a position far away from the pipe bodies 61, a disc 21 being provided on a side wall of the impeller 2 close to the first partition 10, and the disc 21 extending along the radial direction of the impeller 2; and
a driving device 3, including a stator and a rotor, where the stator 31 is disposed on an outer wall of the first partition 10, the stator 31 cooperates with the rotor 32, the rotor 32 and the stator 31 are disposed along a radial direction 200, the rotor 32 is located on one side of an inner wall of the stator 31, the magnetic fields of the stator 31 and the rotor 32 are tangent along an axial direction 100.

The rotor 32 is disposed on the disc 21, or the rotor 32 drives the disc 21 to rotate by means of an intermediate piece, and when the impeller 2 rotates, it can drive the liquid to flow.

In practical work, there may be one set of driving device 3 or two sets of driving devices 3, that is, the one set of driving device is installed inside any one of the liquid chambers 11a, or the two sets of driving devices 3 are respectively installed inside the two liquid chambers 11a.

When the impeller 2 rotates, the liquid passes through the water inlet 102, the first liquid chamber 111, the pipe bodies 61, the second water tank 12, the second liquid chamber 112 (one driving device 3 may be disposed at the position of the second liquid chamber 112), and the water outlet 101 in turn, thereby achieving heat exchange of the heated liquid and transporting the cooled liquid to the heating elements through the water outlet; therefore, cooling is realized.

This embodiment of this application has the following technical effects.

Firstly, the liquid chambers 11a and an outer wall of the first water tank 11 are independent of each other, so that the liquid will not affect circuit components, and the service life and safety of the driving device 3 are guaranteed.

Secondly, the stator 31 and the rotor 32 are disposed radially to achieve axial tangency, so that the overall thickness of the driving device 3 is reduced; furthermore, the first water tank 11 and the water pump are integrally designed, making the structure simpler and the volume smaller, which effectively improves the aesthetics of a water cooling structure for the computer.

Thirdly, the structure is simpler, and there is no need for a concave-convex structure between a water chamber and a pump chamber to achieve the tangency between the stator 31 and the rotor 32; a radial structure is simply adopted, so that the mold production cost is lower and the market competitiveness is effectively improved.

Lastly, under the same output torque, speed and power, compared with a radial flux motor, the axial flux motor (i.e., the driving device 3 mentioned in the present application) has the advantages that: the axial size is shortened by 50% or more, which is more suitable for occasions with high space requirements; and the weight is reduced by about 50%, so that the maneuverability of equipment can be greatly improved, and lightweight is achieved.

The direction of a pump seat may be set vertically or radially, and the corresponding direction can also be changed accordingly.

Specifically, the stator 31 includes a bracket 311 and magnetic induction coils 312, where the magnetic induction coils 312 are disposed on the bracket 311 at intervals, and the magnetic induction directions of the magnetic induction coils 312 are axial; and the rotor 32 is provided with a plurality of permanent magnets 320, the structure of which may be referred to as an axial flux motor, and the rotation of the rotor 32 is controlled by controlling the direction of current.

In the first embodiment, when the permanent magnets 320 are disposed on the disc 21, the stator 31 directly drives the permanent magnets 320 and pushes the impeller 2 to rotate, and the first partition 10 is disposed between the stator 31 and the rotor 32. This structure cancels an air gap, thus overcoming the problem of unstable heat dissipation in the axial flux motor; and that is, the rotor 32 is located in the liquid chamber and can fully dissipate heat. In principle, the magnetic field of the permanent magnets 320 is stable, so that the corresponding main damaged component is the stator 31 (i.e., the part of the magnetic induction coils 312). Therefore, even if a cooling assembly is damaged, the stator 31 can be replaced, which effectively improves the convenience of overhauling; and the rotor 32 and the disc 21 are integrally shaped by injection molding, thereby effectively protecting the structure of the rotor 32 and improving the stability of the permanent magnets 320.

Specifically, the magnetic field projection area of the stator 31 is consistent with that of the rotor 32, thereby ensuring the stability of the drive and avoiding the problem of magnetically induced losses. The permanent magnets 320 are fan-shaped and are distributed on the rotor 32, and the permanent magnets 320 include S poles and N poles, which are adjacent to each other, so that magnetic fields are tangent. The first partition 10 has a planar structure.

In the second embodiment, the rotor 32 is pivotally mounted between the stator 31 and the first partition 10, first magnetic members 321 are disposed on a lower wall of the rotor 32, the disc 21 is provided with second magnetic members 322 cooperating with the first magnetic members 321, and the first partition 10 is disposed between the rotor 32 and the disc 21. Generally speaking, the rotor 32 is also provided with structures such as iron cores for fixing the permanent magnets 320. When the permanent magnets 320 are integrated by injection moulding, the use of the iron cores can also be reduced, and the permanent magnets can be fixed with their magnetic poles.

Specifically, the driving device 3 is a single module, and the driving device 3 is installed on the outer wall of the first partition 10, which facilitates the maintenance of the driving device 3. In principle, the permanent magnets 320 of the impeller 2 will not be damaged. Therefore, the rotation of the impeller 2 can be realized by replacing the driving device 3.

Specifically, the driving device 3 is disposed on a pump housing 33, and the pump housing 33 is fixed to the first water tank 11 by means of screws, and of course, the pump housing can also be installed and fixed by using a buckle structure.

Specifically, the impeller includes blades 22 disposed on an inner wall of the disc 21, the blades 22 are distributed circumferentially on the disc 21, and the blades 22 extend to an outer peripheral wall or a side wall of the disc 21. Specifically, the blades 22 may have arc-shaped, strip-shaped or curved-surface structures, so that the liquid can be enabled to flow in a predetermined direction.

Specifically, a first rotating shaft 7 extends towards the direction of the liquid chamber from a side wall of the first partition 10, the first rotating shaft 7 is available for installation of the impeller 2, and the first rotating shaft 7 extends along both sides or one side of the liquid chamber, that is, the impeller 2 may be of a biaxial structure or a uniaxial structure, so as to ensure the rotation stability of the impeller 2 and guarantee the rotation concentricity.

A bearing is disposed between the first rotating shaft 7 and the impeller 2, where the bearing may be of a corrosion-resistant structure such as a ceramic bearing, thereby improving the stability in use.

Specifically, the first partition 10 is provided with a pivot portion 10a in an extending manner, and the pivot portion 10a is available for installation of the rotor 32 so as to enable the rotor to rotate. Of course, for the rotor 32 with a disc structure, the pivot portion 10a may also be a bearing located on an outer side of the rotor 32, or a second rotating shaft located in the middle of the rotor 32, or bearings located on inner and outer sides of the device.

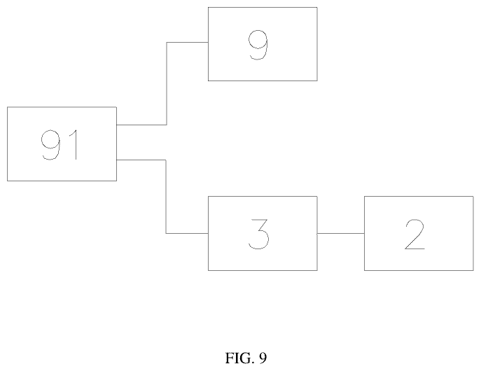

As shown in FIG. 9, specifically, the liquid chamber is provided with a sensor 9, and the sensor 9 is configured to detect the water temperature, water quality, liquid pressure and liquid level of the liquid in the liquid chamber; and the sensor is connected to a control device 91, the control device 91 is also connected to the driving device 3, and the control device is capable of controlling the rotation speed of the impeller 2 based on the data of the sensor.

Specifically, the liquid chamber 11a includes the first liquid chamber 111 and the second liquid chamber 112, and the driving device(s) 3 is/are installed inside the first liquid chamber 111 or/and the second liquid chamber 112.

Specifically, the cross section of the liquid chamber 11a in which the driving device 3 is installed is circular, so that the liquid can be enabled to flow in a predetermined direction.

Specifically, the water inlet and the water outlet are provided at an upper wall position and/or a side wall position of the first water tank 11.

Specifically, the second liquid chamber 112 is not provided with the driving device 3, the second liquid chamber 112 is provided with a second partition 112b at a position between the water inlet and the pipe bodies 61, and a filter layer is provided on the second partition 112b. The filter layer can filter impurities generated due to a copper-aluminum reaction in the liquid, so as to prevent the problem of performance degradation caused by impurities completely accumulating in a water channel and blocking same.

Specifically, the bracket 311 is a printed circuit board (PCB) or an iron core, and the magnetic induction coils 312 are disposed on the bracket 311.

In the actual design, it is preferable to wind the PCB with the magnetic induction coils 312, so as to facilitate circuit control, and make the thickness smaller.

Specifically, when the bracket 311 is a PCB, a groove 51 is formed in a side wall of the first water tank 11, the PCB is disposed in the groove 51, and a back cover 52 (i.e., the pump housing 33) is also disposed on the side of the groove 51 away from the PCB. In order to facilitate the installation of the stator 31, according to actual requirements, it can be set to a structure suitable for the length of the first water tank 11 or to a structure matched with the first liquid chamber 111, so as to realize the modular production of the driving device 3.

Specifically, the first water tank 11 includes a positioning plate 81 and a main body 8, the main body 8 is detachably mounted on the positioning plate 81, the main body 8 is provided with the liquid chambers 11a, clamping slots 82 are formed in outer peripheral walls of the liquid chambers 11a, sealing rings 83 are disposed inside the clamping slots 82, and the positioning plate 81 is connected to end portions of the pipe bodies 61, so that the installation is simpler.

Specifically, there are two groups of pipe bodies 61, and each of the two groups of pipe bodies 61 has a plurality of individual pipe bodies 61. The two groups of pipe bodies 61 are divided into a water inlet pipe body 6a and a water outlet pipe body 6b, two ends of the water inlet pipe body 6a are respectively connected to the second liquid chamber 112 and the second water tank 12, and two ends of the water outlet pipe body 6b are respectively connected to the first liquid chamber 111 and the second water tank 12.

Specifically, the second liquid chamber 112 is provided with a through hole 112a, the through hole 112a penetrates inner and outer walls of the second liquid chamber 112, and the through hole 112a is available for installation of a water injection pipe 62, which facilitates the addition or replacement of the liquid.

The foregoing descriptions are merely exemplary embodiments of the present disclosure, and are not intended to limit the patent scope of present disclosure. Under the inventive concept of the present disclosure, equivalent structural variations made by using the contents of the description and drawings of the present disclosure, or direct/indirect applications of the contents thereof in other related technical fields shall be included in the patent protection scope of the present disclosure.

What is claimed is:

1. An integrated pump water-cooling grid for a computer, comprising:
a water tank, comprising a first water tank and a second water tank, a plurality of pipe bodies being disposed between the first water tank and the second water tank, and radiating fins being disposed between the adjacent pipe bodies; the first water tank being provided with at least two spaced-apart liquid chambers, and the two liquid chambers being respectively connected to a water outlet and a water inlet;
an impeller, pivotally installed in the liquid chamber, a first partition being provided on the first water tank at a position far away from the pipe bodies, a disc being provided on a side wall of the impeller close to the first partition, and the disc extending along the radial direction of the impeller; and
a driving device, comprising a stator and a rotor, wherein the stator is disposed on an outer wall of the first partition, the rotor cooperates with the stator, the rotor and the stator are disposed along a radial direction, the rotor is located on one side of an inner wall of the stator, the magnetic fields of the stator and the rotor are tangent along an axial direction,
wherein the rotor is disposed on the disc, or the rotor drives the disc to rotate by means of an intermediate piece, and
when the impeller rotates, the impeller drives the liquid to flow.

2. The integrated pump water-cooling grid for the computer according to claim 1, wherein the stator comprises a bracket and magnetic induction coils, wherein the magnetic induction coils are disposed on the bracket at intervals, and the magnetic induction directions of the magnetic induction coils are axial; and
the rotor is provided with a plurality of permanent magnets.

3. The integrated pump water-cooling grid for the computer according to claim 2, wherein when the rotor is disposed on the disc, the stator is configured to directly drive the disc to rotate by means of the permanent magnets and drive the impeller to rotate, and the first partition is disposed between the stator and the rotor.

4. The integrated pump water-cooling grid for the computer according to claim 2, wherein the magnetic field projection area of the stator is consistent with that of the rotor; the permanent magnets are fan-shaped and are distributed on the rotor, the permanent magnets with S and N poles are arranged adjacent to each other; and the first partition has a planar structure.

5. The integrated pump water-cooling grid for the computer according to claim 1, wherein the rotor is pivotally mounted between the stator and the first partition, and
first magnetic members are disposed on an outer wall of the rotor, the disc is provided with second magnetic members cooperating with the first magnetic members, and the first partition is disposed between the rotor and the disc.

6. The integrated pump water-cooling grid for the computer according to claim 1, wherein the driving device is a single module, and the driving device is installed on the outer wall of the first partition.

7. The integrated pump water-cooling grid for the computer according to claim 1, wherein the driving device is disposed on a pump housing, and the pump housing is fixed to the first water tank by means of screws.

8. The integrated pump water-cooling grid for the computer according to claim 1, wherein the impeller comprises blades disposed on an inner wall of the disc, the blades are distributed circumferentially on the disc, and the blades extend to an outer peripheral wall or a side wall of the disc.

9. The integrated pump water-cooling grid for the computer according to claim 1, wherein the first partition is provided with a pivot portion, and the pivot portion is available for installation of the rotor so as to enable the rotor to rotate.

10. The integrated pump water-cooling grid for the computer according to claim 1, wherein the liquid chamber is internally provided with a sensor,
the sensor is configured to detect the water temperature, water quality, liquid pressure and liquid level of the liquid in the liquid chamber; and
the sensor is connected to a control device, the control device is also connected to the driving device, and the control device is capable of controlling the rotation speed of the impeller based on the detection data of the sensor.

11. The integrated pump water-cooling grid for the computer according to claim 1, wherein the liquid chamber comprises the first liquid chamber and the second liquid chamber, and the driving device is installed inside the first liquid chamber or/and the second liquid chamber.

12. The integrated pump water-cooling grid for the computer according to claim 11, wherein the cross section of the liquid chamber in which the driving device is installed is circular.

13. The integrated pump water-cooling grid for the computer according to claim 1, wherein the water inlet and the water outlet are provided at an upper wall position and/or a side wall position of the first water tank.

14. The integrated pump water-cooling grid for the computer according to claim 11, wherein the second liquid chamber is not provided with the driving device, the second liquid chamber is provided with a second partition at a position between the water inlet and the pipe bodies, and a filter layer is provided on the second partition.

15. The integrated pump water-cooling grid for the computer according to claim 2, wherein the bracket is a printed circuit board (PCB) or an iron core, and the magnetic induction coils are disposed on the bracket.

16. The integrated pump water-cooling grid for the computer according to claim 15, wherein when the bracket is the PCB, a groove is formed in an outer wall of the first water tank, the PCB is disposed in the groove, and a back cover is also disposed on the side of the groove away from the PCB.

17. The integrated pump water-cooling grid for the computer according to claim 11, wherein the first water tank comprises a positioning plate and a main body, the main body is detachably mounted on the positioning plate, the main body is internally provided with the liquid chambers, the positioning plate is connected to end portions of the pipe bodies, clamping slots are formed in outer peripheral walls of the liquid chambers, and sealing rings are disposed inside the clamping slots.

18. The integrated pump water-cooling grid for the computer according to claim 11, comprising a water inlet pipe body and a water outlet pipe body, wherein each of the water inlet pipe body and the water outlet pipe body comprises the plurality of pipe bodies, two ends of the water inlet pipe body are respectively connected to the second liquid chamber and the second water tank, and two ends of the water outlet pipe body are respectively connected to the first liquid chamber and the second water tank.

19. The integrated pump water-cooling grid for the computer according to claim 11, wherein the second liquid chamber is provided with a through hole, the through hole penetrates inner and outer walls of the second liquid chamber, and the through hole is available for installation of a water injection pipe.

20. The integrated pump water-cooling grid for the computer according to claim 1, wherein a first rotating shaft is disposed on an inner wall of the first partition, the first rotating shaft extends in the direction of the liquid chamber, the first rotating shaft is available for installation of the impeller, and the first rotating shaft extends along both sides or one side of the liquid chamber.
